(19) United States
(12) Patent Application Publication
(10) Pub. No.: US 2005/0003673 A1
(43) Pub. Date: Jan. 6, 2005

(54) Thin film resistor etch

(76) Inventor: Omid Mahdavi, Tucson, AZ (US)

Correspondence Address: W. Daniel Swayze, Jr.;Texas Instruments Incorporated, M/S 3999, PO Box 655474, Dallas, TX, 75265, US

(21) Appl. No.: 10/612,123

(22) Filed: Jul. 2, 2003

(51) Int. Cl. H01L 21/302; H01L 21/461

(52) U.S. Cl. 438/710

(57) ABSTRACT

A thin film resistor is formed by employing a plasma etch on a resistor material layer. The resistor material layer can be fabricated employing a nickel chromium (NiCr) alloy, or nickel chromium aluminum (NiCrAl) alloy. A plasma etch is performed in a magnetically enhanced low pressure environment with a chlorine chemistry mixture. The magnetically enhanced low pressure environment and the sufficiently selective chlorine chemistry provide a substantially controlled plasma etch of the resistor material layer to form the thin film resistor. In-situ thickness measurements or an endpoint optical emission system can be employed to determine when to halt the etching process to mitigate damage associated with etching of the layer underlying the thin film resistor.

### TECHNICAL FIELD

The present invention relates to semiconductor devices and, more particularly, to a thin film resistor etch.

### BACKGROUND OF THE INVENTION

In the semiconductor industry, there is a continuing trend toward higher device densities. To achieve these high densities, there has been and continues to be efforts toward scaling down device dimensions to submicron levels (e.g., below 0.35 microns) on semiconductor substrates. In order to accomplish such high device packing density, smaller and smaller features sizes are required. This may include the width and spacing of metal interconnecting lines, spacing and diameter of contact holes, and the surface geometry such as corners and edges of various features. Conventionally, analog precision and mixed signal devices have not been fabricated employing these submicron densities. This is because the precision of the analog devices and the selection of available materials for precision analog devices have been overriding factors over device density and device speed. However, with the increased importance of reduced size and increased speeds in analog applications, and the increased integration of digital and analog devices in substrates, there is an increased desired to employ analog devices in submicron processes.

Conventionally, doped polysilicon is employed as a material of a resistor in a semiconductor fabrication. However, the resistance of a doped polysilicon resistor is controlled by the size of the predetermined length and area of the doped polysilicon layer. Therefore, to increase the resistance per unit of a resistor, thin film resistor materials are employed such as silicon chromium (SiCr) alloy, nickel chromium (NiCr) alloy, tantalum nitride, titanium nitride, and tungsten. Thin film resistors are very attractive components for high precision analog and mixed signal applications. In addition to a low thermal coefficient of resistance, low voltage coefficient of resistance, and good resistor matching they provide good stability under stress.

### SUMMARY OF THE INVENTION

The following presents a simplified summary of the invention in order to provide a basic understanding of some aspects of the invention. This summary is not an extensive overview of the invention. It is intended to neither identify key or critical elements of the invention nor delineate the scope of the invention. Its sole purpose is to present some concepts of the invention in a simplified form as a prelude to the more detailed description that is presented later.

The present invention relates to the formation of a thin film resistor (TFR) by employing a plasma etch on a resistor material layer. In one aspect of the invention, the resistor material layer is fabricated employing a nickel chromium (NiCr) alloy, or nickel chromium aluminum (NiCrAl) alloy. A plasma etch is performed in a magnetically enhanced low pressure environment with a chlorine chemistry mixture. The magnetically enhance low pressure environment and selected chemistry provides a substantially controlled plasma etch of the resistor material layer to form the TFR. Additionally, a plasma etch optical emission sensing device can be employed to determine when to halt the etching process to mitigate damage associated with etching of the layer underlying the TFR.

To the accomplishment of the foregoing and related ends, certain illustrative aspects of the invention are described herein in connection with the following description and the annexed drawings. These aspects are indicative, however, of but a few of the various ways in which the principles of the invention may be employed and the present invention is intended to include all such aspects and their equivalents. Other advantages and novel features of the invention will become apparent from the following detailed description of the invention when considered in conjunction with the drawings.

### BRIEF DESCRIPTION OF THE DRAWINGS

FIG. 1 illustrates a schematic block diagram of a processing system for forming a TFR in accordance with an aspect of the present invention.

FIG. 2 illustrates a schematic cross-sectional view of a semiconductor structure having a dielectric layer formed over a metal interconnect layer in accordance with an aspect of the present invention.

FIG. 3 illustrates a schematic cross-sectional view of the structure of FIG. 2 after deposition of a thin film resistor (TFR) material layer and a capping layer in accordance with an aspect of the present invention.

FIG. 4 illustrates a schematic cross-sectional view of the structure of FIG. 3 undergoing an etch step in accordance with an aspect of the present invention.

FIG. 5 illustrates a schematic cross-sectional view of the structure of FIG. 4 after the etch step is substantially complete in accordance with an aspect of the present invention.

FIG. 6 illustrates a schematic cross-sectional illustration of the structure of FIG. 5 after deposition of a metallization layer over the capping layer in accordance with an aspect of the present invention.

FIG. 7 illustrates a schematic cross-sectional illustration of the structure of FIG. 6 undergoing an etch step in accordance with an aspect of the present invention.

FIG. 8 illustrates a schematic cross-sectional illustration of the structure of FIG. 7 after the etch step is substantially complete in accordance with an aspect of the present invention.

FIG. 9 illustrates a schematic cross-sectional view of a TFR formed over a dielectric layer residing over a semiconductor substrate with a dielectric layer overlying the TFR in accordance with an aspect of the present invention.

FIG. 10 illustrates a schematic cross-sectional illustration of the structure of FIG. 9 after deposition of a photoresist material layer over the dielectric layer in accordance with an aspect of the present invention.

FIG. 11 illustrates a schematic cross-sectional illustration of the structure of FIG. 10 after the etch step is substantially complete in accordance with an aspect of the present invention.

FIG. 12 illustrates a schematic cross-sectional illustration of the structure of FIG. 11 after undergoing a barrier layer deposition in accordance with an aspect of the present invention.

FIG. 13 illustrates a schematic cross-sectional illustration of the structure of FIG. 12 after deposition of a metallization layer over the barrier layer in accordance with an aspect of the present invention.

FIG. 14 illustrates a schematic cross-sectional illustration of the structure of FIG. 13 undergoing an etch step in accordance with an aspect of the present invention.

FIG. 15 illustrates a schematic cross-sectional illustration of the structure of FIG. 14 after the etch step is substantially complete in accordance with an aspect of the present invention.

FIG. 16 illustrates a schematic block diagram of processing system that employs a measurement system in accordance with an aspect of the present invention.

FIG. 17 illustrates a flow diagram of a methodology for fabricating a TFR in accordance with an aspect of the present invention.

### DETAILED DESCRIPTION

The present invention relates to the formation of a TFR by employing a plasma etch on a resistor material layer formed of a nickel chromium (NiCr) alloy, or nickel chromium aluminum (NiCrAl) alloy. The plasma etch can be performed in a magnetically enhanced (e.g., in a magnetic field) low pressure (e.g., at or below 30 mTorr) environment with a chlorine and boron tri-chloride plasma chemistry mixture. The plasma etch mitigates resist adhesion issues associated with wet etch processes. The plasma etch also mitigates resistor width issues associated with resistor designs in addition to reducing the costs associated with employing wet etch chemistries versus plasma process gases.

Conventionally, a NiCr or NiCrAl resistor is formed by etching a NiCr or NiCrAl resistor material layer over a dielectric layer. A patterned photoresist layer is then provided over the resistor material layer to form the pattern for the thin film resistor. A wet etch having a nickel soluble compound is then performed on the NiCr or NiCrAl layer to remove the resistor material layer around the patterned photoresist and to leave the remaining NiCr or NiCrAl below the photoresist to form the thin film resistor.

A wet etch is employed because it is difficult to vaporize nickel by-products formed during a plasma process due to their very low vapor pressures. However, wet etch techniques are not desirable for submicron processes due to undercutting properties associated with wet etching. Additionally, due to the strong acidic chemistries (low pH) associated with wet etches, photoresist adhesion issues result when poor adhesion to conductive materials cause the wet etch chemistries to lift the photoresist material layer from the underlying surface. Also, many chrome etch chemistries also have a limited shelf life due to their composition which makes them less desirable for use in a manufacturing environment.

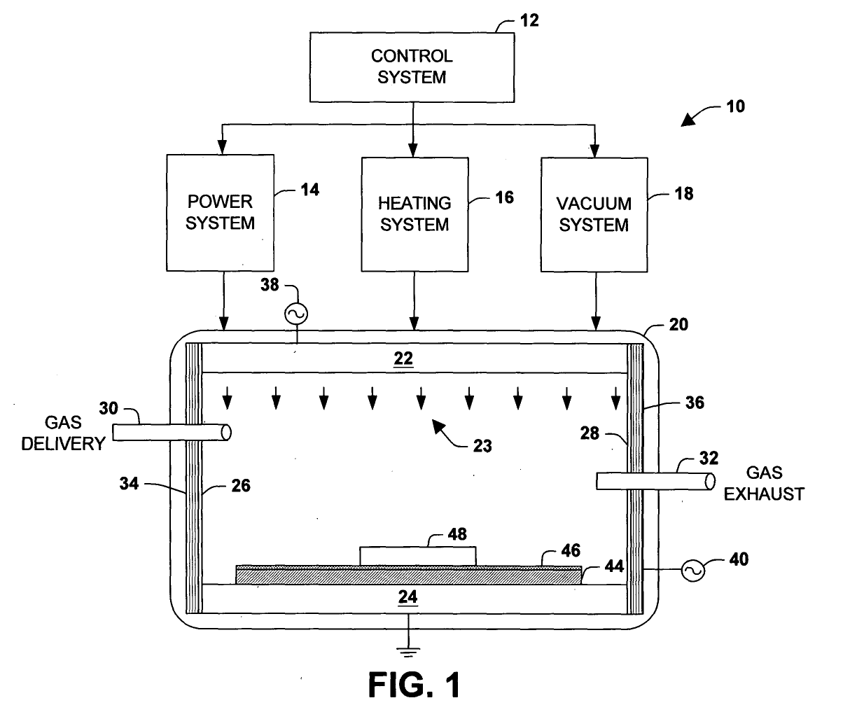

FIG. 1 illustrates a processing system 10 for forming a thin film resistor in accordance with an aspect of the present invention. In this example, the system 10 etches the thin film resistor material layer 46 over a substrate 44. The resistor material layer 46 can be formed using a nickel chromium (NiCr) alloy, or a nickel chromium aluminum (NiCrAl) alloy. The substrate 44 can be a semiconductor layer with one or more intervening layers disposed between the semiconductor substrate and the resistor material layer 46.

The resistor material layer 46 can be formed employing a chemical vapor deposition (CVD) process. Examples of CVD processes that may be utilized, in accordance with an aspect of the present invention, include Low Pressure CVD (LPCVD), Plasma Enhanced CVD (PECVD), and Rapid Thermal CVD (RTCVD). It is to be appreciated, however, that the present invention is applicable to other types of thin film formation, such as other deposition techniques (e.g., Physical Vapor Deposition (PVD), Metal Organic Chemical Vapor Deposition (MOCVD), Pulsed Laser Deposition (PLD)) and film growth techniques).

The processing system 10 can be a magnetically enhanced reactive ion etcher (MERIE) apparatus or, other high-density plasma etcher (e.g., an electron cyclotron resonance (ECR) plasma reactor, Inductively-Coupled Plasma (ICP) reactor, Dual Plasma Source (DSP) reactor). In the example, of FIG. 1, the processing system 10 is illustrated as performing a plasma etch 23 on the thin film material layer 46. A patterned photoresist material layer 48 resides over the thin film resistor material layer 46, such that a TFR is formed by the plasma etch 23.

The processing system includes a control system 12 that controls parameters associated with an environment within a processing chamber 20. The parameters associated with a plasma etch system can include: pressure, gas mixture, gas flow rate, temperature, power, magnetic field and the substrate position relative to the plasma. The control system 12 controls a power system 14, a heating system 16 and a vacuum pressure system 18 for controlling parameters associated with the environment of the processing chamber 20 during the plasma etch 23. The control system 12 also controls a gas delivery system (not shown) coupled to a gas delivery conduit 30, and a gas exhaust system (not shown) coupled to a gas exhaust conduit 32. The gas delivery system and gas delivery conduit 30 provide the desired etchant gases into the processing chamber 20 for subsequent plasma etching of the semiconductor device. The gas exhaust system removes etchant by-products from the process chamber to mitigate contamination as a result of the plasma etching 23 of the semiconductor device and also to allow plasma reactions to proceed.

The power system 14 controls an RF generator 38 that is employed to induce an electric field between an anode 22 and a cathode 24. The electrical field causes the reactants in etchant gases that enter the chamber 20 to dissociate and recombine with electrons to create reactive ions or plasma. The reactive ions then bombard the surface of the resistor material layer 46 to physically and/or chemically react with the surface of the resistor material layer 46. The bombardment of the reactive ions also causes the desorption of by-products that are removed by the gas exhaust system.

The power system 14 also controls an AC supply 40 that is employed to induce a variable magnetic field in the chamber via electrostatic coils or magnets 34 and 36. It is to be appreciated that a number of techniques can be employed to provide the desired magnetic field within the process chamber 20. The magnetic field, which is applied parallel to the substrate, is provided to increase the plasma density by creating a greater degree of disassociation to the etchant chemistry resulting in a greater degree of ionization. The use of a magnetic field provides a more efficient highly-directional etch with low-energy ions and less wafer damage than what typically results without a magnetic field. Additionally, the denser plasma with more reactive species and charged particles increases the etch rate.

The heating system 16 control the heat associated with the walls of the process chamber 20 in addition to the heat associated with the cathode 24 of the chamber 20. The vacuum system 18 controls the pressure within the process chamber 20.

In one aspect of the present invention, a plasma etch is performed on the resistor material layer 46. The control system 12 sets a low pressure (e.g., at or below 30 mTorr) or vacuum pressure (e.g., milliTorr range) processing chamber environment via the vacuum system 18. In one aspect of the invention, the pressure of the processing chamber environment is set to have a pressure of about 5 mTorr to about 15 mTorr (e.g., about 10 mTorr). The plasma etch is selected at a power (associated with the electric field) of about 700 watts to about 1100 watts (e.g., about 900 Watts) by the control system via the power system 14 and the RF generator 38. The resistor material layer 46 is etched with a plasma gas(es), such as a mixture of chlorine (Cl₂) and boron tri-chloride (BCl₃) provided by the gas delivery system via the gas delivery conduit 30. The mixture of Cl₂/BCl₃ can be selected at a ratio of about 4:1. It is to be appreciated that other mixture ratios (e.g., about 3:1, about 5:1, about 6:1, about 7:1, etc., about 10:1, about 11:1, etc., about 20:1) of Cl₂/BCl₃ can be selected to provide the desired chemistry for etching the resistor material layer 46.

The control system 12 selects a magnetically enhanced processing chamber environment, for example, by providing a magnetic field in the chamber 20 of about 45 Gauss to about 55 Gauss (e.g., about 50 Gauss) via the power system 14 through the electrostatic magnets 34 and 36. The control system 12 sets the temperature of the cathode 24 (and/or anode 22) at about 80° C. to about 90° C. (e.g., about 85° C.), and the temperature of the chamber walls 26 and 28 to be about 60° C. to about 70° C. (e.g., about 65° C.) via the heating system 16 to mitigate adsorption of the plasma reaction by-products on the interior structures of the process chamber 20.

It has been determined that the above selected etching parameters provide substantially improved processing results and also provide reasonable process times (i.e., etching time and gas exhaust time). For example, it has been determined that a process time of about 60 seconds to about 120 seconds (e.g., about 90 seconds) is achievable for a NiCrAl film thickness of about 160 Angstroms to about 200 Å (e.g., about 180 Å), and a process time of about 40 seconds to about 60 seconds (e.g., about 50 seconds) is achievable for a NiCr film thickness of about 100 Å to about 150 Å (e.g., about 125 Å). Additionally, it has been determined that reasonable oxide loss (e.g., less than about 500 Å for PECVD silicon oxides) of the underlying dielectric layer is achievable.

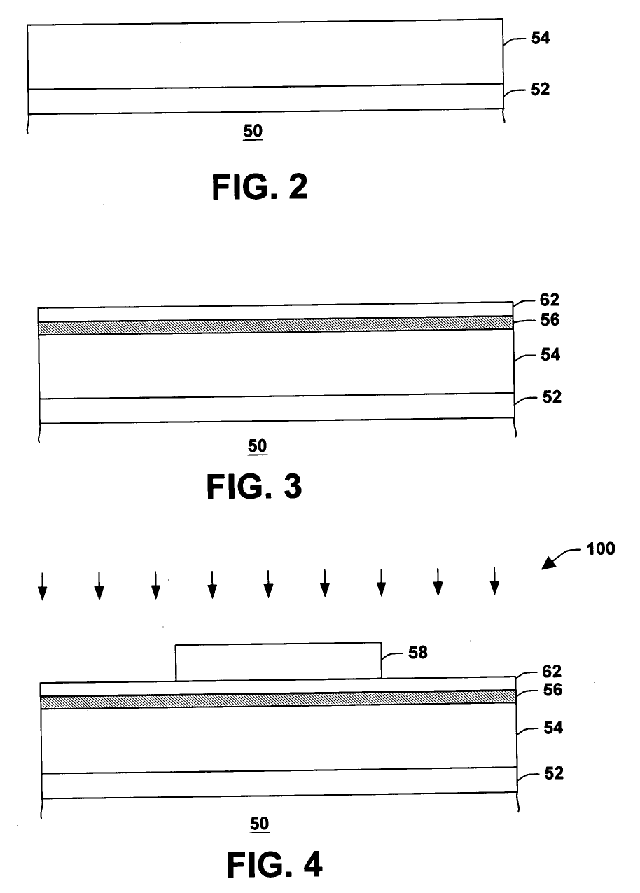

FIGS. 2-8 illustrate a methodology for fabrication of a thin film resistor (TFR) in accordance with an aspect of the present invention. FIG. 2 illustrates a metal interconnect 52 (e.g., aluminum, aluminum alloy, copper, copper alloy, tungsten, tungsten alloy) formed over a dielectric layer 50. The dielectric layer 50 can be formed over a semiconductor substrate and any number of intervening layers. The semiconductor and any intervening layers have been omitted from the Figures for the sake of clarity. Although omitted from the Figures, the layers beneath the dielectric layer 50 will comprise any number of active devices including MOS and/or bipolar transistors as well as any number of metal interconnect levels.

As illustrated in FIG. 2, an inter-level dielectric layer 54 is formed over the metal interconnect layer 52. The inter-level dielectric layer 54 can comprise silicon oxide formed using any suitable method including chemical vapor deposition Low Pressure Chemical Vapor Deposition (LPCVD), Plasma Enhanced Chemical Vapor Deposition (PECVD), sputtering or high density plasma chemical vapor deposition (HDPCVD). In one aspect of the present invention, the inter-level dielectric layer 54 is formed using at least one of TEOS silicon oxides, PECVD silicon oxides, silicon nitrides, silicon oxynitrides, silicon carbides, spin-on glass (SOG) such as silsesquioxanes and siloxane, xerogels or any other suitable material. In another aspect of the present invention, the thickness of the inter-level dielectric layer 54 is in the range from about 3000 Å to about 8000 Å, and the thickness of the metal interconnect layer 52 is in the range from about 3000 Å to about 5000 Å. The inter-level dielectric layer 54 can be planarized by a chemical mechanical polish (CMP).

FIG. 3 illustrates the structure after a resistor material layer 56 is deposited over the inter-level dielectric layer 54. The resistor material layer 56 can be formed using a nickel chromium aluminum (NiCrAl) alloy, or a nickel chromium (NiCr) alloy. The resistor material can be selected based on a particular implementation and a desired result. Any suitable technique for forming the resistor material layer 56 can be employed such as Low Pressure Chemical Vapor Deposition (LPCVD), Plasma Enhanced Chemical Vapor Deposition (PECVD), sputtering or high density plasma chemical vapor deposition (HDPCVD) techniques to a thickness suitable for forming a TFR.

In one aspect of the present invention, the thickness of the resistor material layer 56 is in the range from about 160 Å to about 200 Å (e.g., for the NiCrAl alloy), and in another aspect of the present invention the thickness is in the range from about 100 Å to about 150 Å, (e.g., for the NiCr alloy).

A capping layer 62 is formed over the formed over the resistor material layer 56 (FIG. 3). The capping layer 62 is employed to protect the resistor material layer 56 from subsequent processing steps and is optional based on the particular resistor material being employed in addition to the selection of subsequent etchants. The capping layer 62 can be formed using titanium nitride or titanium tungsten. It is to be appreciated that the capping layer 62 can comprise multiple layers formed using layers comprised of the same or differing conductive material.

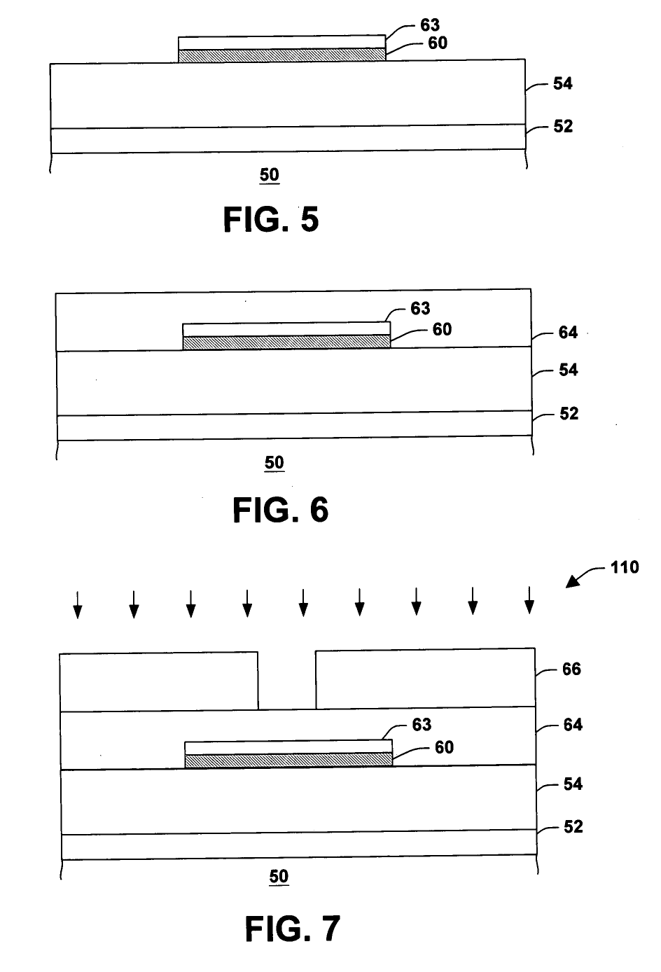

A photoresist layer 58 (FIG. 4) is formed and patterned over the resistor material layer 56 and the optional capping layer 62. The photoresist layer 58 is used to define a thin film resistor (TFR) 60 (FIG. 5) during an etching process 100. The photoresist layer 88 has a thickness of about 10,000 Å to about 20,000 Å. However, it is to be appreciated that the thickness thereof may be of any dimension suitable for carrying out the present invention. A final deep ultra-violet cure may be performed on the patterned photoresist depending on its type and thickness. If the capping material is present, it can be isotropically etched with a plasma gas(es), such as sulfuric hexafluoride (SF₆) containing fluorine ions to form a TFR cap 63 (FIG. 5). Then an etch 100 is performed on the resistor material layer 56 to form a TFR 60 (FIG. 5). The TFR 60 is formed by plasma etching the resistor material layer 56 using the photoresist layer 58 as a masking layer. The resultant structure is illustrated in FIG. 5 after the remaining patterned photoresist 58 is stripped (e.g., ashing in an O₂/H₂O plasma).

The TFR 60 can have a length of about 1 micron to about 100 microns (e.g., about 2 microns). The resistor material layer 56 is etched employing a plasma etch in a low pressure magnetically enhanced environment having a pressure of about 5 mTorr to about 15 mTorr (e.g., about 10 mTorr) at a power of about 700 watts to about 1100 watts (e.g., about 900 Watts). The resistor material layer 56 can be etched with a plasma gas(es), such as a mixture of chlorine (Cl₂) and boron tri-chloride (BCl₃) in a magnetically enhanced reactive ion etcher (MERIE) apparatus or, other high-density plasma etchers (e.g., an electron cyclotron resonance (ECR) plasma reactor, Inductively-Coupled Plasma (ICP) reactor, Dual Plasma Source (DSP) reactor). The mixture of Cl₂/BCl₃ can be selected at a ratio of about 4:1. It is to be appreciated that other mixture ratios (e.g., about 3:1, about 5:1, about 6:1, about 7:1, etc., about 10:1, about 11:1, etc., about 20:1) of Cl₂/BCl₃ can be selected to provide the desired chemistry for etching the resistor material layer 56.

The plasma etch 100 can be performed in a magnetically enhanced environment having a magnetic field of about 45 Gauss to about 55 Gauss (e.g., about 50 Gauss). The cathode (and/or anode) of the plasma etcher can be selected to have a temperature of about 80° C. to about 90° C. (e.g., about 85° C.), and the temperature of the chamber walls selected to be about 60° C. to about 70° C. (e.g., about 65° C.).

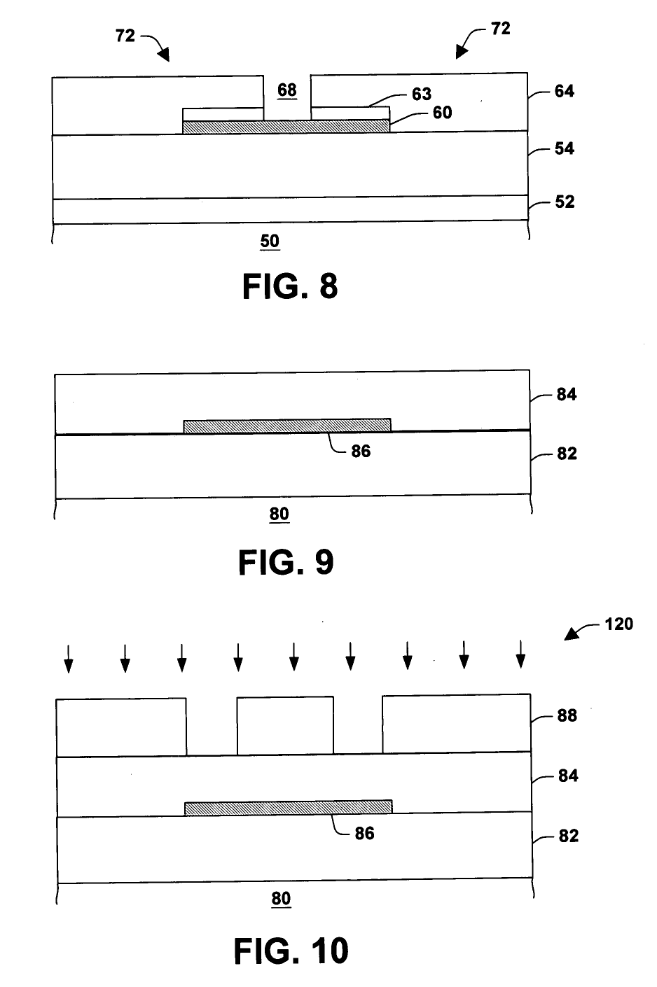

A metallization layer 64 (e.g. aluminum, aluminum alloy, copper, copper alloy, tungsten, tungsten alloy) is then deposited over the TFR cap 63, the TFR 60 and the inter-level dielectric layer 54 employing conventional metal deposition techniques as illustrated in FIG. 6. After the formation of the metallization layer 64, a patterned photoresist layer 66 (FIG. 7) is formed on the metallization layer 64. The patterned photoresist layer 66 is employed to form a via 68 (FIG. 8) during an etch 110 that extends through the metallization layer 64 and the capping layer 63 to expose a central portion of the TFR 64. The etch 110 is performed on the metallization layer to form the required electrical connections to the TFR, such that a first portion of the metallization layer 64 forms a first contact 70 and a second portion of the metallization layer 64 forms a second contact 72.

If the metallization layer is formed of aluminum or aluminum alloys, the metallization layer can be dry etched in a plasma etcher via the use of a chlorine chemistry, or it can be wet etched via the use of a number of standard acids (e.g., phosphoric acid). Following the etch 110 of the metallization layer, the TFR 60 is exposed to an oven baking process (e.g., at 500° C.) to cause the TFR 60 to stabilize into defined layers. Any number of intervening layers can then be formed over the resultant structure illustrated in FIG. 8.

FIGS. 9-15 illustrate an alternate methodology for fabrication of a thin film resistor (TFR) with TFR vias formed in a dielectric layer in accordance with an aspect of the present invention. FIG. 9 illustrates a dielectric layer 82 formed over a semiconductor substrate 80. Any number of intervening layers can be provided between the dielectric layer 82 and the semiconductor substrate 80. The dielectric layer 80 can comprise silicon oxide formed using any suitable method including chemical vapor deposition Low Pressure Chemical Vapor Deposition (LPCVD), Plasma Enhanced Chemical Vapor Deposition (PECVD), High Density Chemical Plasma Vapor Deposition (HDPCVD). In one aspect of the present invention, the dielectric layer 82 is formed using at least one of TEOS silicon oxides, PECVD silicon oxides, silicon nitrides, silicon oxynitrides, silicon carbides, spin-on glass (SOG) such as silsesquioxanes and siloxane, xerogels or any other suitable material. In another aspect of the present invention, the thickness of the dielectric layer 82 is in the range from about 3000 Å to about 8000 Å. The dielectric layer 82 can be planarized by a chemical mechanical polish (CMP).

A TFR 86 is disposed on the dielectric layer 82. The TFR 86 has a length of about 1 micron to about 100 microns (e.g., about 2 microns) and a thickness in the range from about 160 Å to about 200 Å (e.g., NiCrAl alloy), or in the range from about 100 Å to about 150 Å, (e.g., NiCr alloy). The TFR 86 is formed employing a plasma etching process similar to the plasma etching process 100 as illustrated in FIG. 4. The TFR 86 is exposed to an oven baking process (e.g., at 500° C.) to cause the TFR 86 to stabilize into defined layers.

A dielectric layer 84 is provided over the TFR 86. The dielectric layer 84 is employed to protect the TFR 86 from subsequent processing steps. Additionally, the material and thickness of the dielectric layer 84 is selected so as not to interfere with a post-fabrication laser trim process of the TFR 86. The dielectric layer 84 can be formed using TEOS oxides or any other suitable oxide. It is to be appreciated that the dielectric layer 84 can comprise multiple layers formed using layers comprised of the same or differing material.

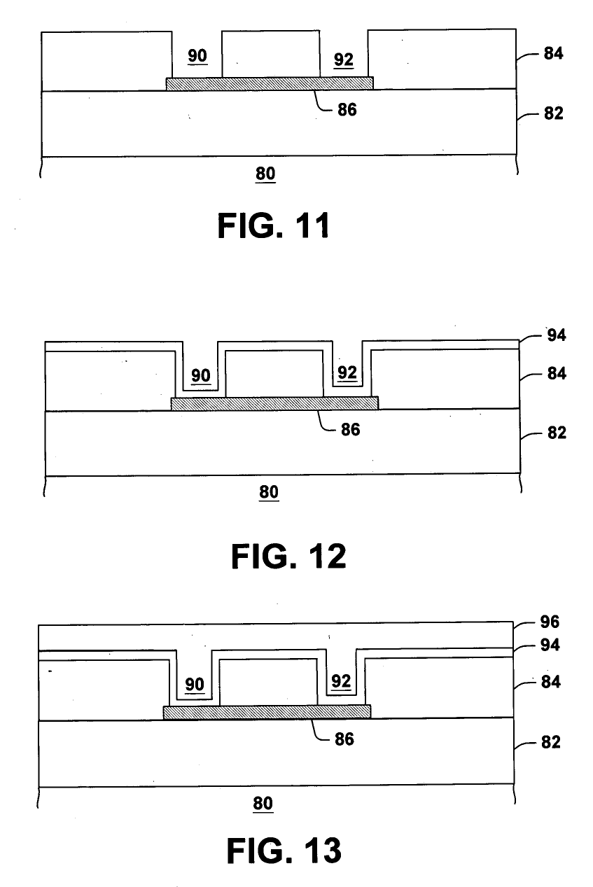

A photoresist layer 88 (FIG. 10) is formed on the dielectric layer 84. The photoresist layer 88 has a thickness of about 10,000 Å to about 20,000 Å. However, it is to be appreciated that the thickness thereof may be of any dimension suitable for carrying out the present invention. The photoresist layer 88 may be formed over the dielectric layer 86 via conventional spin-coating or spin casting deposition techniques. The photoresist layer 88 has a thickness suitable for functioning as a mask for etching the underlying dielectric layer 84 to form vias 90 and 92 (FIG. 11) to the TFR 86.

The dielectric layer 84 is shown undergoing an etching process 120 (FIG. 10) wherein the patterned photoresist 88 served as an etch mask layer for processing or etching the underlying dielectric layer 84. The etching process 120 can be a dry etch that is selective to dielectric layer 84 as compared to the patterned photoresist layer 88, and the underlying TFR 86. It is to be appreciated that any suitable etch methodology for selectively etching the underlying dielectric layer 84 can be employed.

For example, the dielectric layer 84 can be isotropically etched with a plasma gas(es), such as sulfuric hexafluoride (SF₆) containing fluorine ions, in a commercially available etcher, such as a MERIE apparatus or, alternatively, an electron cyclotron resonance (ECR) plasma reactor to replicate the mask pattern of the patterned photoresist layer 88 to thereby provide TFR vias 90 and 92 (FIG. 11) through the dielectric layer 84. Alternatively, the patterned dielectric layer 84 can be wet etched using a number of HF containing solutions. The etching process 120 provides via access to the TFR 86.

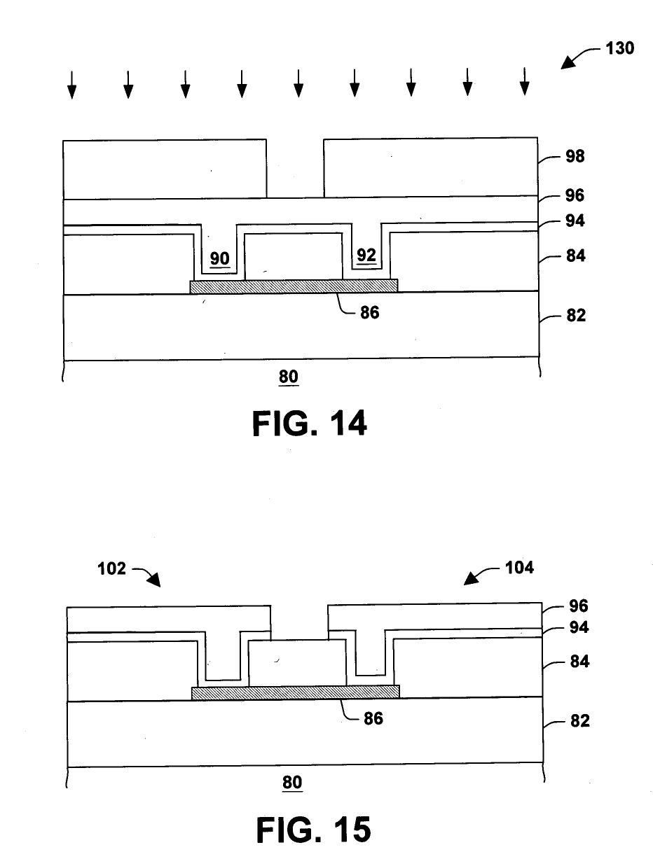

FIG. 12 illustrates the structure after a barrier layer 94 is deposited over the dielectric layer 84. The barrier layer 94 can be formed using titanium nitride or titanium tungsten, and is employed to protect the TFR 86 from subsequent processing. A metallization layer 96 (e.g. aluminum, aluminum alloy, copper, copper alloy, tungsten, tungsten alloy) is then deposited over the barrier layer 94 employing conventional metal deposition techniques, as illustrated in FIG. 13. After the formation of the metallization layer 96, a patterned photoresist layer 98 (FIG. 14) is formed on the metallization layer 96. The patterned photoresist layer 98 is employed to form the required conductive electrical leads to the resistor network beneath during an etch 130 that extends through the metallization layer 96 and the barrier layer 94 to form a first contact portion 102 and a second contact portion 104. Any number of intervening layers can then be formed over the resultant structure illustrated in FIG. 15.

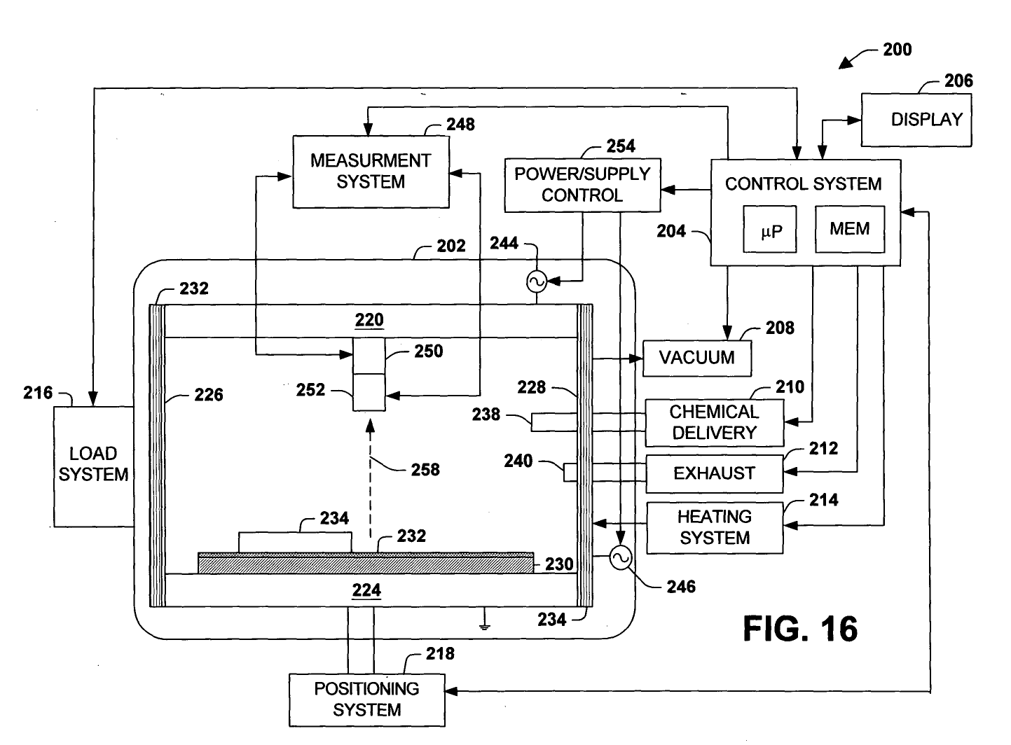

FIG. 16 illustrates a processing system 200 that employs a measurement system 248 in accordance with an aspect of the present invention. The measurement system 248 can control the in-situ layer thickness of a resistor material layer during a deposition and/or a plasma etch process, and can also be employed to control the in-situ layer thickness of other material layers during deposition and/or etching processes. In this example, the system 200 forms a resistor material layer 232 (e.g., NiCr, NiCrAl) over a substrate 230. The substrate 230 can be formed from a semiconductor layer and one or more intervening layers disposed between the semiconductor layer and the resistor material layer 232.

The resistor material layer 232 can be formed by a chemical vapor deposition (CVD) technique. Examples of CVD processes that may be utilized, in accordance with an aspect of the present invention, include Low Pressure CVD (LPCVD), Plasma Enhanced CVD (PECVD), and Rapid Thermal CVD (RTCVD). It is to be appreciated, however, that the present invention is applicable to other types of thin film formation, such as other deposition techniques (e.g., Physical Vapor Deposition (PVD), Metal Organic Chemical Vapor Deposition (MOCVD), Pulsed Laser Deposition (PLD)) and film growth techniques). It is to be appreciated that the devices associated with material deposition are typically performed in another process chamber other than the process chamber in which the etch is performed:

The system 200 includes a process chamber 202 that includes a support, such as a stage 224 (or chuck) operative to support the substrate 230, such as a wafer. A positioning system 218 is operatively connected to a support for positioning the stage 224 at a desired position within the chamber 202. The stage 224 also functions as a cathode for an electric field generator of the system 200. The system 200 includes a control system 204 that controls parameters associated with the processing chamber 202. Parameters associated with the process chamber can include: pressure, gas mixture, gas flow rate, temperature, RF power, magnetic field and the substrate position relative to the plasma.

The control system 204 includes a processor, such as a microprocessor or CPU, coupled to a memory. The processor 204 receives measured data from the measurement system 248. The processor 204 also is operatively coupled to a vacuum system 208, a chemical deliver system 210, an exhaust system 212, a heating system 214, a power/supply control system 254, the positioning system 218 and a load system 216. The control system 204 is programmed/and or configured to control and operate the various components within the processing system 200 in order to carry out the various functions described herein. The control system 204 controls parameters associated with an environment of the processing chamber 202 during a plasma etch of the resistor material layer 232 in addition to controlling parameters associated with other etching and/or deposition processes.

The power/supply control system 254 controls an RF generator 244 that is employed to induce an electric field between an anode 220 and a cathode 224. The power/supply control system 254 also controls an AC supply 246 that is employed to induce a magnetic field in the chamber via coils 232 and 234. It is to be appreciated that a number of techniques can be employed to provide the desired magnetic fields within the process chamber 202. The power supply/control system 254 also provides operating power to the system 200 in addition to power control to the RF generator 244 and the AC supply 246.

The heating system 214 control the heat associated with walls 226 and 228 of the process chamber 202 in addition to the heat associated with the cathode 224 of the chamber 202. The vacuum system 208 controls the pressure within the process chamber 202. The load system 216 is operatively connected to the chamber 202 for loading and unloading substrates (e.g., wafers) into and out of the processing chamber. The load system 216 typically is automated to load and unload the wafers into the chamber at a controlled rate.

The system 200 further may include a display 206 operatively coupled to the control system 204 for displaying a representation (e.g., graphical and/or text) of one or more process conditions, such as layer thickness, temperature, chemical etchant information, chamber pressure, magnetic field, etc. The display 206 further may show a graphical and/or textual representation of the monitored process conditions of the process chamber in addition to measured properties at various locations along the surface of the substrate.

The chemical delivery system 210 is operationally coupled to the chamber 202 for selectively providing chemical etchant materials into the chamber during subsequent etching processes. The chemical etchant materials for etching the various layers are selected to be readily interchangeable as to facilitate the utilization of a single process chamber for at least a substantial portion of the subsequent etching processes. The chemical etchant materials are provided into the chamber 202 through a conduit 238. Post process reactants are then removed by the exhaust system 212 via a conduit 240.

For example, during etching of the resistor material layer 232 to form a TFR, the control system 204 sets a low pressure processing chamber environment via the vacuum system 208 having a pressure of about 5 mTorr to about 15 mTorr (e.g., about 10 mTorr). The plasma etch is selected at a power of about 700 watts to about 1100 watts (e.g., about 900 Watts) by the control system 204 via the power supply/control system 254 and the RF generator 244. The control system 204 selects a magnetically enhanced environment having a magnetic field of about 45 Gauss to about 55 Gauss (e.g., about 50 Gauss) via the power supply/control system 248 through the electrostatic magnets 232 and 234. The control system 204 sets the temperature of the cathode 224 at about 80° C. to about 90° C. (e.g., about 85° C.), and the temperature of the chamber walls 226 and 228 to be about 60° C. to about 70° C. (e.g., about 65° C.) via the heating system 214.

A mixture of Cl₂/BCl₃ is introduced into the process chamber 202 via the chemical delivery system 210. The mixture of Cl₂/BCl₃ can be selected at a ratio of (e.g., about 3:1, about 4:1, about 5:1, about 6:1, about 7:1, etc., about 10:1, about 11:1, etc., about 20:1). The resistor material layer 232 is then etched via a plasma etch to form a TFR beneath a patterned photoresist layer 234. After etching of the resistor material layer 232, by-products of the etching process are removed via the conduit 240 of the exhaust system 212. Oxygen (02 plasma) is then provided into the chamber 202 to remove the remaining patterned photoresist material layer 234. The remaining photoresist material layer and oxygen are then removed via the exhaust system 212.

A capping layer (e.g., titanium tungstum) can be formed over the TFR. During etching of the capping layer, a mixture of sulfuric hexafluoride (SF₆) containing fluorine ions is introduced into the processing chamber. The remaining titanium tungsten and sulfuric hexafluoride (SF₆) are then removed via the exhaust system 212. Additionally, a contact material layer (e.g., aluminum) can be deposited after TFR vias are formed to provide TFR contacts. A chlorine or fluorine etch can be employed to remove excess contact material layer to provide the TFR contacts. Other chemical etchants can be readily introduced and removed via the chemical delivery system 210 for different film layers (e.g., fluorine etches for SiO₂; chlorine and fluorine etches for aluminum; chlorine, fluorine and bromine etch for silicon).

A measurement system 248 is operative to measure film thickness in-situ, in accordance with an aspect of the present invention. The measurement system 248 can be an ellipsometry system operative to measure the thickness of the resistor material layer 232 during a deposition process, and/or the thickness of the resistor material layer 232 during a plasma etching process to form a TFR. The measurement system can also be an endpoint optical emission system. This system utilizes the phenomenon of spectral emissions to sense endpoint or the end of the TFR etch process. Spectral emission is the characteristic of a substance to emit light at specific discrete wavelengths when subjected to some energy excitation, in this case the excited byproducts of a plasma reaction.

For example, during etching of a NiCr or NiCrAl resistor material layer, the by-product chromium has an endpoint emission 258 of 4250 Å, which can be monitored by a detector of 252 of the measurement system 248. Once the endpoint emission 258 is no longer detected, changes wavelength, or decreases sufficiently, the etching has reached the underlying substrate below the resistor material layer 232. The etching process can then be terminated.

The measurement system 248 can include a broadband light source 250 that can emit a light beam for in situ thickness measurements. This light source can be employed during the deposition of the resistor material layer 232 to achieve a desired thickness of the resistor material layer 232. This light source need not be employed during an etching process of the resistor material layer 232 to form a TFR, since the emissions of the etched material can be measured as opposed to the reflective light from the light source 250. The measurement system can also include other devices such as a lens assembly, a polarizer, an analyzer in addition to the detector 252 and the light source 250.

The etched emissions 258, which is received at the detector 252 has emission properties (e.g., magnitude and/or phase), which may be employed to determine an indication of resistor material layer thickness. A plurality of emissions also may be detected at various locations on the substrate to obtain corresponding measurements of layer thickness substantially concurrently during the fabrication process. The concurrent measurements, in turn, provide an indication of the uniformity of layer thickness across the substrate. Once the desired thickness is achieved, the deposition or etching process can be terminated. It is to be appreciated that the measurement system 248 can be employed to measure deposition and/or etching of other material layers.

It is to be appreciated that other types of measurement systems can be employed to monitor the deposition and/or etching process of the resistor material layer. The measurement system, for example, may employ a scatterometry technique using spectroscopic ellipsometry to measure thickness of the resistor material layer. The measurement system 248 could utilize in-situ laser scattering or laser doppler anemometry. It is also to be appreciated that the measurement system could employ polychromatic interferometer system or a monochromatic interferometer system to measure the thickness of the resistor material layer 232 during the etching process.

As a result, the system 200 provides for monitoring process conditions, including layer thickness and other sensed process-related conditions, associated with the TFR formation process within the chamber 202. The monitored conditions provide data based on which the control system 204 may implement feedback process control so as to form a TFR having a desired thickness, width and area.

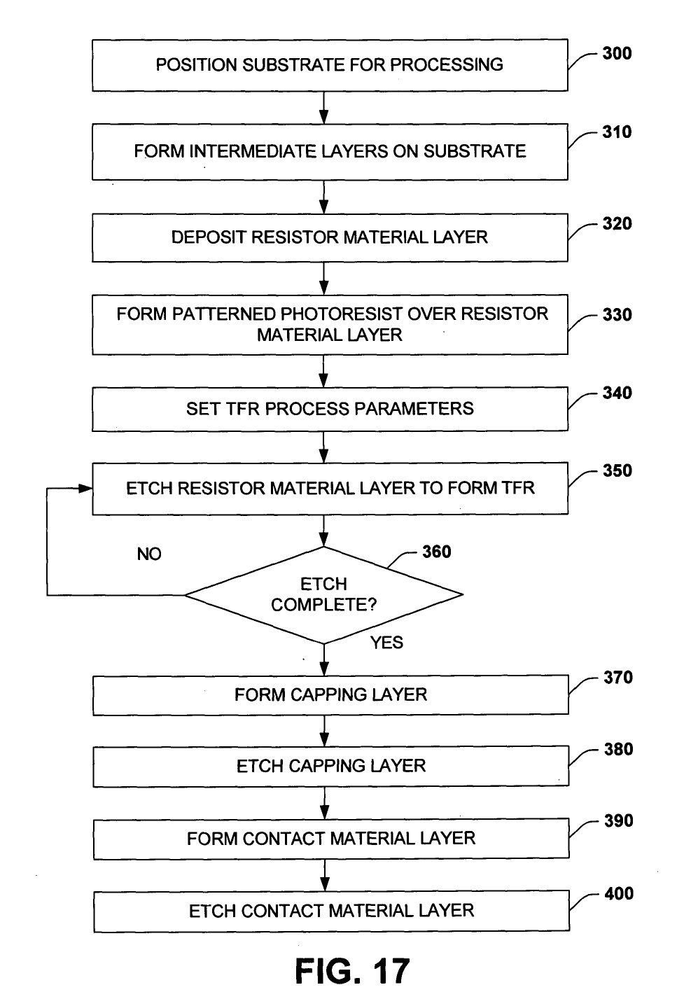

In view of the foregoing structural and functional features described above, a methodology in accordance with various aspects of the present invention will be better appreciated with reference to FIG. 17. While, for purposes of simplicity of explanation, the methodology of FIG. 17 is shown and described as executing serially, it is to be understood and appreciated that the present invention is not limited by the illustrated order, as some aspects could, in accordance with the present invention, occur in different orders and/or concurrently with other aspects from that shown and described herein. Moreover, not all illustrated features may be required to implement a methodology in accordance with an aspect the present invention.

FIG. 17 illustrates a methodology for fabricating a TFR in accordance with an aspect of the present invention. The methodology begins at 300 where a substrate is positioned in a chamber for processing, for example, via a loading system and/or positioning system. At 310, one or more intermediate layers are formed on the substrate. For example, a dielectric layer can be formed over the substrate with any numbering of intervening layers formed between the substrate and the dielectric layer. The layers beneath the dielectric layer can comprise any number of active devices including MOS and/or bipolar transistors as well as any number of metal interconnect levels.

At 320, a resistor material layer is deposited over the substrate followed by a capping layer (e.g., titanium tungsten, titanium nitride) over the TFR if desired. The resistor material layer can be formed of NiCr or NiCrAl. The thickness of the resistor material layer can be based on a desired resistor value. In one aspect of the present invention, the thickness of the resistor material layer 56 is in the range from about 25 Å to about 300 Å. A photoresist material layer is then formed over the resistor material layer and patterned via conventional techniques at 330. The patterned photoresist material layer provides the desired pattern of the subsequent TFR to be formed. The methodology then proceeds to 340.

At 340, the TFR plasma etching parameters are set. For example, the resistor material layer can be etched employing a plasma etch in a low pressure environment having a pressure of about 5 mTorr to about 15 mTorr (e.g., about 10 mTorr) at a power of about 700 watts to about 1100 watts (e.g., about 900 Watts). The resistor material layer can be etched with a plasma gas(es), such as a mixture of chlorine (Cl₂) and boron tri-chloride (BCl₃). The mixture of Cl₂/BCI₃ can be selected at a ratio of about 4:1. It is to be appreciated that other mixture ratios (e.g., about 3:1, about 5:1, about 6:1, about 7:1, etc., about 10:1, about 11:1, etc., about 20:1) of Cl₂/BCl₃ can be selected to provide the desired chemistry for etching the resistor material layer. The plasma etch can be performed in a magnetically enhanced environment having a magnetic field of about 45 Gauss to about 55 Gauss (e.g., about 50 Gauss). The cathode of the plasma etcher can be selected to have a temperature of about 80° C. to about 90° C. (e.g., about 85° C.), and the temperature of the chamber walls selected to be about 60° C. to about 70° C. (e.g., about 65° C.).

At 350, etching of the resistor material/capping layer to form the TFR begins. The capping layer is etched with a different chemistry (e.g., fluoride chemistry) than the resistor material layer. For example, the capping layer can be isotropically etched with a plasma gas(es), such as sulfuric hexafluoride (SF₆) containing fluorine ions. During etching of the resistor material layer, in situ measurement of the emissions (e.g., chromium emissions) is performed to determine the amount of the resistor material layer that is removed. The methodology then proceeds to 360 to determine if the etch has been completed based at least in part on the emissions measured (e.g., resistor material layer removed). If the etch is not complete (NO), the methodology continues etching at 350. If the etch is indicated as being complete (YES), the reactant by-products caused by the etching are removed and the methodology proceeds to 370.

At 370, a dielectric layer (e.g., TEOS oxide) is formed over the TFR. The dielectric layer is then etched at 380 to form TFR vias. The dielectric layer is etched with a different chemistry (e.g., fluoride chemistry) than the resistor material layer. For example, the dielectric layer can be isotropically etched with a plasma gas(es), such as sulfuric hexafluoride (SF₆) containing fluorine ions. The patterned dielectric layer can also be wet etched using a number of HF containing solutions. The methodology then proceeds to 390. Alternatively, 370 can be skipped (i.e. no dielectric encapsulation of the TFR), and we can proceed directly to 390.

At 390, a contact material layer (e.g., aluminum, aluminum alloy, copper, copper alloy, tungsten, tungsten alloy) is formed over the capping layer filling the vias with contact material to form conductive TFR contacts. At 400, the contact material layer is etched to remove a predetermined thickness of the contact material layer. A chlorine or fluorine etch can be employed to remove excess contact material layer to provide the TFR contacts.

What has been described above includes examples and implementations of the present invention. Because it is not possible to describe every conceivable combination of components, circuitry or methodologies for purposes of describing the present invention, one of ordinary skill in the art will recognize that many further combinations and permutations of the present invention are possible. Accordingly, the present invention is intended to embrace all such alterations, modifications and variations that fall within the spirit and scope of the appended claims.

1. A system for forming a thin film resistor (TFR), comprising:
a substrate having a resistor material layer formed thereon, the resistor material layer formed from one of nickel chromium (NiCr) and nickel chromium aluminum (NiCrAl); and
a plasma etcher that etches the resistor material layer with a plasma etch chemistry to form the TFR.

2. The system of claim 1, the plasma etch chemistry comprising a mixture of chlorine (Cl₂) and boron tri-chloride (BCl₃).

3. The system of claim 1, the mixture of chlorine (Cl₂) and boron tri-chloride (BCl₃) having a mixture ratio of one of about 3:1, about 4:1, about 5:1, about 10:1 and about 20:1.

4. The system of claim 1, the plasma etcher further comprising a processing chamber that provides a magnetically enhanced environment during etching of the resistor material layer.

5. The system of claim 4, the magnetically enhanced environment having a magnetic field of about 45 Gauss to about 55 Gauss.

6. The system of claim 1, the plasma etcher further comprising a processing chamber that provides a low pressure environment in the processing chamber during etching of the resistor material layer.

7. The system of claim 6, the low pressure environment in the process chamber being about 5 mTorr to about 15 mTorr.

8. The system of claim 1, the plasma etcher etching the resistor material layer at a power of about 700 watts to about 1100 watts.

9. The system of claim 1, the substrate residing in a processing chamber of the plasma etcher, the processing chamber having an anode and a cathode operative to generate an electric field and create plasma, the processing chamber also having walls, at least one of the cathode and anode being set at a temperature of about 80° C. to about 90° C. and the walls being set at a temperature of about 60° C. to about 70° C.

10. The system of claim 1, further comprising a measurement system that monitors spectral emissions from the plasma during the etching of the resistor material layer to determine when to halt the etching of the resistor material layer.

11. The system of claim 10, the spectral emission including chromium emissions.

12. A method for forming a thin film resistor (TFR), comprising:
forming a dielectric layer over a substrate;
forming a resistor material layer formed from one of nickel chromium (NiCr) and nickel chromium aluminum (NiCrAl) on the dielectric layer; and
etching the resistor material layer with a plasma etch chemistry to form the TFR.

13. The method of claim 12, the plasma etch chemistry being a mixture of chlorine (Cl₂) and boron tri-chloride (BCl₃), the mixture ratio of Cl₂:BCl₃ being one of about 3:1, about 4:1, about 5:1, about 10:1 and about 20:1.

14. The method of claim 12, further comprising exposing the resistor material layer to a magnetically enhanced low pressure environment during etching of the resistor material layer.

15. The method of claim 14, the magnetically enhanced low pressure environment having a magnetic field of about 45 Gauss to about 55 Gauss.

16. The method of claim 14, the magnetically enhanced low pressure environment having a pressure of about 5 mTorr to about 15 mTorr.

17. The method of claim 12, the etching the resistor material layer being at a power of about 700 watts to about 1100 watts.

18. The method of claim 12, further comprising monitoring plasma spectral emissions during etching of the resistor material to determine when to halt the etching of the resistor material layer.

19. The method of claim 18, the measured emissions comprising chromium emissions.

20. The method of claim 12, further comprising forming a capping layer over the TFR.

21. The method of claim 20, further comprising etching TFR vias in the capping layer with a sulfuric hexafluoride (SF₆) etch chemistry.

22. The method of claim 12, further comprising forming a dielectric layer over the TFR and etching TFR vias in the dielectric layer to expose ends of the TFR, and filling the TFR vias with a contact material to form TFR contacts.

23. A system for forming a thin film resistor (TFR), comprising:
means for plasma etching at least one of a nickel chromium (NiCr) and a nickel chromium aluminum (NiCrAl) resistor material layer formed on a substrate with a chemistry selective to the at least one of nickel chromium (NiCr) and nickel chromium aluminum (NiCrAl) to form the TFR; and
means for providing a low pressure magnetically enhanced environment for the plasma etching.

24. The system of claim 23, the plasma etch chemistry being a mixture of chlorine (Cl₂) and boron tri-chloride (BCl₃), the mixture ratio of Cl₂:BCl₃ being one of about 3:1, about 4:1, about 5:1, about 10:1 and about 20:1.

25. The system of claim 23, the magnetically enhanced low pressure environment having a magnetic field of about 45 Gauss to about 55 Gauss and a pressure of about 5 mTorr to about 15 mTorr.

26. The system of claim 23, further comprising a measurement system that monitors spectral emissions from the plasma during the etching of the resistor material layer to determine when to halt the etching of the resistor material layer.
